(19) United States
(12) Patent Application Publication
(10) Pub. No.: US 2026/0304888 A1
(43) Pub. Date: Oct. 1, 2026

(54) SEMICONDUCTOR DEVICE

(71) Applicant: FUJI ELECTRIC CO., LTD., Kanagawa (JP)

(72) Inventors: Toshiki SUZUKI, Matsumoto-city (JP); Yasunori AGATA, Matsumoto-city (JP); Tohru SHIRAKAWA, Matsumoto-city (JP)

(21) Appl. No.: 19/578,887

(22) Filed: Mar. 26, 2026

(30) Foreign Application Priority Data
Apr. 1, 2025 (JP) 2025-060778

(51) Int. Cl. H10D 64/23; H10D 12/00; H10D 62/10; H10D 84/00

(52) U.S. Cl. CPC H10D 64/232; H10D 12/481; H10D 62/127; H10D 84/161

(57) ABSTRACT

There is provided a semiconductor device including: an emitter electrode which is provided above an semiconductor substrate, and which has a first main region, a second main region, and a third main region; a gate pad which is provided above the semiconductor substrate; a gate metal layer which is electrically connected to the gate pad; and a gate runner portion which is electrically connected to the gate metal layer, in which a plurality of trench portions have a plurality of gate trench portions, the emitter electrode has a first emitter bridge portion which connects the first main region to the second main region, and a second emitter bridge portion which connects the second main region to the third main region, and below the first emitter bridge portion, a gate trench portion different from a gate trench portion which is provided below the second emitter bridge portion is provided.

The contents of the following patent application(s) are incorporated herein by reference: NO. 2025-060778 filed in JP on Apr. 1, 2025.

### BACKGROUND

### 1. Technical Field

The present invention relates to a semiconductor device.

### 2. Related Art

Patent Document 1 discloses that “a connection portion 15 is formed to electrically connect emitter electrodes 14 on both sides of first gate wiring 18 and second gate wiring 20”.

### RELATED ART DOCUMENTS

### Patent Document

Patent Document 1: Japanese Patent Application Publication No. 2010-98250

### BRIEF DESCRIPTION OF THE DRAWINGS

FIG. 1 is a top plan view showing an example of a semiconductor device 100.

FIG. 2 is an enlarged view of a region R1 in FIG. 1.

FIG. 3 is a view showing an example of a cross section a-a′ in FIG. 2.

FIG. 4 is an enlarged view of a region R2 in FIG. 1.

FIG. 5 is a view showing an example of a cross section b-b′ in FIG. 4.

FIG. 6 is a top plan view showing an example of a semiconductor device 1100 according to a comparison example.

FIG. 7 is a graph showing a relationship between a position of an emitter bridge portion 53 and a parasitic resistance value in a gate trench portion 40.

FIG. 8 is a top plan view showing another example of the semiconductor device 100 according to an embodiment.

FIG. 9 is a top plan view showing another example of the semiconductor device 100 according to an embodiment.

### DESCRIPTION OF EXEMPLARY EMBODIMENTS

Hereinafter, the present invention will be described through embodiments of the invention, but the following embodiments do not limit the invention according to the claims. In addition, not all of the combinations of features described in the embodiments are essential to the solving means of the invention.

In the present specification, one side of a semiconductor substrate in a direction parallel to a depth direction is referred to as an “upper” side or a “front” side and another side is referred to as a “lower” side or a “back” side. One surface of two principal surfaces of a substrate, a layer, or another member is referred to as an upper surface or a front surface, and another surface is referred to as a lower surface or a back surface. “Upper”, “lower”, “front”, and “back” directions are not limited to a direction of gravity, or a direction when a semiconductor device is mounted.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicating a height direction with respect to the ground. It should be noted that a +Z axis direction and a −Z axis direction are directions opposite to each other. When a Z axis direction is described without describing the signs, it means that the direction is parallel to a +Z axis and a −Z axis.

In the present specification, orthogonal axes parallel to the front surface and the back surface of the semiconductor substrate are referred to as the X axis and the Y axis. In addition, an axis perpendicular to the front surface and the back surface of the semiconductor substrate is referred to as the Z axis. In the present specification, the direction of the Z axis may be referred to as a depth direction. In addition, in the present specification, a direction parallel to the front surface and the back surface of the semiconductor substrate may be referred to as a horizontal direction, including the X axis and the Y axis.

A region from the center of the semiconductor substrate in the depth direction to the front surface of the semiconductor substrate may be referred to as a front surface side. Similarly, a region from the center of the semiconductor substrate in the depth direction to the back surface of the semiconductor substrate may be referred to as a back surface side.

When a term such as “same” or “equal” is used herein, it may encompass a case where an error due to a variation in manufacturing or the like is included. The error is, for example, within 10%.

In the present specification, a conductivity type of a doping region doped with impurities is described as a P type or an N type. In the present specification, the impurities may particularly mean either donors of the N type or acceptors of the P type and may be described as dopants. In the present specification, doping means introducing the donors or the acceptors into the semiconductor substrate and turning it into a semiconductor presenting a conductivity type of the N type, or a semiconductor presenting a conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is N_{D} and the acceptor concentration is N_{A}, the net doping concentration at any position is given as N_{D}-N_{A}. In the present specification, the net doping concentration may be simply described as the doping concentration.

The donor has a function of supplying electrons to a semiconductor. The acceptor has a function of receiving electrons from the semiconductor. The donor and the acceptor are not limited to the impurities themselves. For example, a VOH defect in which a vacancy (V), oxygen (O), and hydrogen (H) present in the semiconductor are attached together functions as the donor which supplies the electrons. In the present specification, the VOH defect may be referred to as a hydrogen donor.

In the present specification, a description of a P+ type or an N+ type means a higher doping concentration than that of the P type or the N type, and a description of a P-type or an N-type means a lower doping concentration than that of the P type or the N type. In the present specification, a unit system is the SI base unit system unless otherwise noted. Although a unit of length may be indicated by cm, it may be converted to meters (m) before calculations.

A chemical concentration in the present specification refers to an atomic density of an impurity measured regardless of an electrical activation state. The chemical concentration (atomic density) can be measured by secondary ion mass spectrometry (SIMS), for example. The net doping concentration described above can be measured by capacitance-voltage profiling (CV method). In addition, a carrier concentration measured by spreading resistance profiling (SRP method) may be set as the net doping concentration. The carrier concentration measured by the CV method or the SRP method may be a value in a thermal equilibrium state. In addition, in a region of the N type, the donor concentration is sufficiently higher than the acceptor concentration, and thus the carrier concentration of the region may be set as the donor concentration. Similarly, in a region of the P type, the carrier concentration of the region may be set as the acceptor concentration. In the present specification, the doping concentration of the N type region may be referred to as the donor concentration, and the doping concentration of the P type region may be referred to as the acceptor concentration.

When a concentration distribution of the donor, the acceptor, or the net doping has a peak in a region, a value of the peak may be set as the concentration of the donor, the acceptor, or the net doping in the region. In a case where the concentration of the donor, the acceptor, or the net doping is substantially uniform in a region, or the like, an average value of the concentration of the donor, the acceptor, or the net doping in the region may be set as the concentration of the donor, the acceptor, or the net doping. In the present specification, atoms/cm³ or/cm3 is used to indicate a concentration per unit volume. This unit is used for a concentration of a donor or an acceptor in a semiconductor substrate, or a chemical concentration. A notation of atoms may be omitted.

The carrier concentration measured by the SRP method may be lower than the concentration of the donor or the acceptor. In a range where a current flows when a spreading resistance is measured, carrier mobility of the semiconductor substrate may be lower than a value in a crystalline state. The decrease in carrier mobility occurs when carriers are scattered due to disorder (disorder) of a crystal structure due to a lattice defect or the like.

The concentration of the donor or the acceptor calculated from the carrier concentration measured by the CV method or the SRP method may be lower than a chemical concentration of an element indicating the donor or the acceptor. As an example, in a silicon semiconductor, a donor concentration of phosphorus or arsenic serving as a donor, or an acceptor concentration of boron (boron) serving as an acceptor is approximately 99% of chemical concentrations of these. On the other hand, in the silicon semiconductor, a donor concentration of hydrogen serving as a donor is approximately 0.1% to 10% of a chemical concentration of hydrogen. Each concentration in the present specification may be a value at room temperature. As an example, a value at 300K (Kelvin) (substantially 26.9° C.) may be used for the value at room temperature.

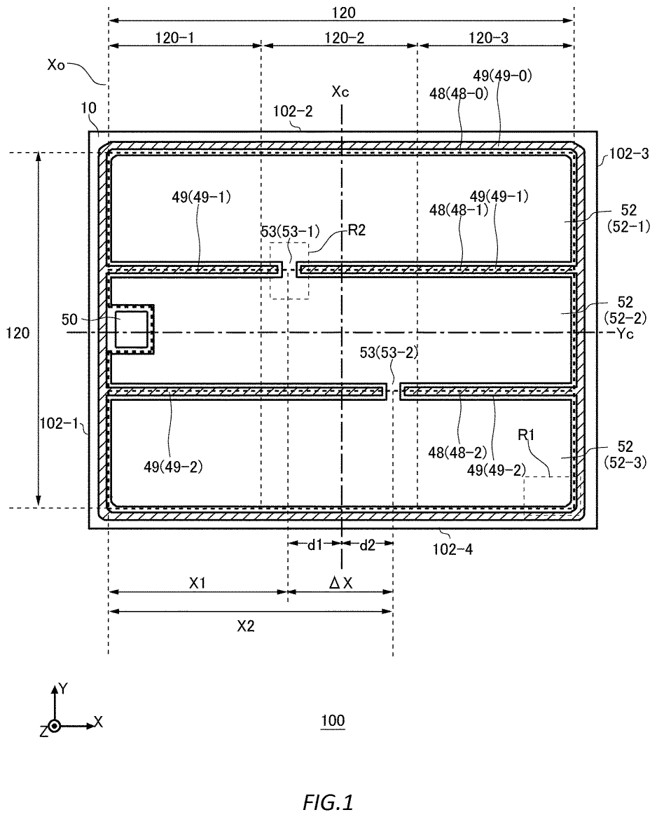

FIG. 1 is a top plan view showing an example of a semiconductor device 100. FIG. 1 shows positions at which respective members are projected on an upper surface of a semiconductor substrate 10. FIG. 1 shows merely some of the members of the semiconductor device 100, and omits illustrations of some of the members.

The semiconductor device 100 includes the semiconductor substrate 10. The semiconductor substrate 10 is a substrate formed of a semiconductor material such as silicon or a compound semiconductor. The semiconductor substrate 10 has an end side 102 in a top view. When simply referred to as the top view in the present specification, it means that the semiconductor substrate 10 is viewed from an upper surface side. The semiconductor substrate 10 of the present example includes two sets of end sides 102 facing each other in the top view. In FIG. 1, the X axis and the Y axis are parallel to any of the end sides 102. In addition, the Z axis is perpendicular to a front surface of the semiconductor substrate 10. In FIG. 1, of the end sides 102 extending in the Y axis direction, the end side 102 on the negative side of the X axis direction is set as an end side 102-1, and clockwise from the edge 102-1, the end sides are referred to as an end side 102-2, an end side 102-3, and an end side 102-4 in order. A plurality of trench portions described below are provided extending in the Y axis direction, and are arrayed along the X axis direction.

The semiconductor substrate 10 is provided with an active portion 120. The active portion 120 is a region through which a main current flows in the depth direction between the upper surface and a lower surface of the semiconductor substrate 10 when the semiconductor device 100 is controlled to be in an On state. Above the active portion 120, an emitter electrode 52 described below is provided. In the top view of the semiconductor substrate 10, the active portion 120 of the present example is a region surrounded by an outer peripheral gate runner 48-0 described below.

The emitter electrode 52 may be divided into a plurality of main regions. The emitter electrode 52 of the present example has a first main region 52-1, a second main region 52-2, and a third main region 52-3. In the present example, the first main region 52-1, the second main region 52-2, and the third main region 52-3 are arrayed, along the Y axis direction, from the positive side (close to the end side 102-2) of the Y axis direction toward the negative side (close to the end side 102-4), in order. In the present example, the first main region 52-1, the second main region 52-2, and the third main region 52-3 are provided spaced apart from each other.

The emitter electrode 52 may have an emitter bridge portion 53 which connects each main region. The emitter bridge portion 53 may be formed of the same material as that of the emitter electrode 52. The emitter bridge portion 53 of the present example has a first emitter bridge portion 53-1 which connects the first main region 52-1 to the second main region 52-2, and a second emitter bridge portion 53-2 which connects the second main region 52-2 to the third main region 52-3.

The first emitter bridge portion 53-1 of the present example is arranged at a position different from that of the second emitter bridge portion 53-2 in the X axis direction. That is, in the X axis direction, when a position of an end portion of the active portion 120 on a gate pad 50 side is set as a reference position Xo, a distance X1 between the first emitter bridge portion 53-1 and the reference position Xo differs from a distance X2 between the second emitter bridge portion 53-2 and the reference position Xo. In the X axis direction, a distance ΔX between the first emitter bridge portion 53-1 and the second emitter bridge portion 53-2 may be 150 μm or more and 500 μm or less.

It should be noted that the reference position Xo may be on a virtual line passing through the end portion of the active portion 120 which is closest to the end side 102-1. The center position between the first emitter bridge portion 53-1 and the second emitter bridge portion 53-2 may be on a virtual center line Xc of the active portion 120 in the X axis direction.

The first emitter bridge portion 53-1 of the present example is provided closer to a gate pad 50 than the virtual center line Xc of the active portion 120 in the X axis direction, and the second emitter bridge portion 53-2 of the present example is provided spaced apart from the gate pad 50 farther than the virtual center line Xc. In the present example, in the X axis direction, a distance d1 between the first emitter bridge portion 53-1 and the virtual center line Xc is equal to a distance d2 between the second emitter bridge portion 53-2 and the virtual center line Xc.

In the present example, the first emitter bridge portion 53-1 and the second emitter bridge portion 53-2 are provided equally offset from the center of the active portion 120, thereby making it possible to reduce a variation in emitter potential in the X axis direction.

In the X axis direction, the distance X1 between the first emitter bridge portion 53-1 and the reference position Xo may be 2.5% or more and 97.5% or less of the distance X2 between the second emitter bridge portion 53-2 and the reference position Xo. In the present example, the distance X1 is 40% or more and 60% or less of the distance X2.

When the active portion 120 is divided into three equal parts in the X axis direction to set a first active region 120-1, a second active region 120-2, and a third active region 120-3, in order of closeness to the gate pad 50, the first emitter bridge portion 53-1 and the second emitter bridge portion 53-2 may be provided in the second active region 120-2.

The active portion 120 is provided with a transistor portion including a transistor element such as an IGBT. The active portion 120 may further be provided with a diode portion including a diode element such as a FWD. The front surface of the semiconductor substrate 10 in the active portion 120 is provided with a plurality of trench portions. The plurality of trench portions of the present example are provided extending in the Y axis direction. The plurality of trench portions include a gate trench portion and a dummy trench portion. The gate trench portion is configured to function as a gate electrode to which a gate potential is applied in the transistor portion. The dummy trench portion is provided in the transistor portion or the diode portion, and an emitter potential is applied to the dummy trench portion. The dummy trench portion is electrically connected to the emitter electrode 52.

The semiconductor device 100 may have one or more pads above the semiconductor substrate 10. The semiconductor device 100 of the present example has the gate pad 50. The gate pad 50 of the present example is provided on the negative side (closer to the end side 102-1) of the X axis direction further than the active portion 120 is. The semiconductor device 100 may be provided with pads such as an anode pad, a cathode pad, and a pad for current detection. These pads may be arranged near the end side 102-3 on the opposite side of the gate pad 50. When the semiconductor device 100 is mounted, each pad may be connected to an external circuit via a wiring line such as a wire.

A gate potential is applied to the gate pad 50. The gate pad 50 is electrically connected to a gate conductive portion of the gate trench portion of the active portion 120. The semiconductor device 100 includes gate wiring that connects the gate pad 50 to the gate trench portion. The gate wiring of the present example has a gate metal layer 49 electrically connected to the gate pad 50 and a gate runner portion 48 electrically connected to the gate metal layer 49. In FIG. 1, the gate metal layer 49 is hatched with a diagonal line, and the gate runner portion 48 is shown with a dashed line.

The gate metal layer 49 is arranged above the semiconductor substrate 10. The gate metal layer 49 may be metal wiring. The gate metal layer 49 of the present example has an outer peripheral gate metal portion 49-0, and a first gate metal portion 49-1 and a second gate metal portion 49-2 which are connected to the outer peripheral gate metal portion 49-0 and which extend in the X axis direction on the active portion 120. In the top view of the semiconductor substrate 10, the outer peripheral gate metal portion 49-0 is arranged between the emitter electrode 52 and the end side 102 of the semiconductor substrate 10. In the top view of the semiconductor substrate 10, the outer peripheral gate metal portion 49-0 of the present example surrounds the active portion 120.

The first gate metal portion 49-1 of the present example extends between the first main region 52-1 and the second main region 52-2, and the second gate metal portion 49-2 of the present example extends between the second main region 52-2 and the third main region 52-3. The first gate metal portion 49-1 and the second gate metal portion 49-2 are provided in the active portion 120, thereby making it possible to reduce a variation in wiring length from the gate pad 50 for each region of the semiconductor substrate 10.

The gate metal layer 49 of the present example is provided separately from the emitter electrode 52. That is, in the top view of the semiconductor substrate 10, in a region surrounded by the first main region 52-1, the second main region 52-2, and the first emitter bridge portion 53-1, the first gate metal portion 49-1 of the present example is provided spaced apart from these; and in the top view of the semiconductor substrate 10, in a region surrounded by the second main region 52-2, the third main region 52-3, and the second emitter bridge portion 53-2, the second gate metal portion 49-2 of the present example is provided spaced apart from these. The first emitter bridge portion 53-1 is sandwiched by the first gate metal portion 49-1 in the X axis direction, and the second emitter bridge portion 53-2 is sandwiched by the second gate metal portion 49-2 in the X axis direction.

The gate runner portion 48 is arranged above the semiconductor substrate 10. The gate runner portion 48 may be wiring formed of a semiconductor such as polysilicon doped with impurities. The gate runner portion 48 of the present example has the outer peripheral gate runner 48-0, and a first gate runner 48-1 and a second gate runner 48-2 which are connected to the outer peripheral gate runner 48-0 and which extend in the X axis direction on the active portion 120.

The outer peripheral gate runner 48-0 of the present example is provided around the active portion 120. In other words, the active portion 120 of the present example refers to a region surrounded by the outer peripheral gate runner 48-0. The outer peripheral gate runner 48-0 of the present example is provided below the outer peripheral gate metal portion 49-0. Note that near the gate pad 50 of the present example, the outer peripheral gate metal portion 49-0 is arranged between the gate pad 50 and the end side 102-1, and the outer peripheral gate runner 48-0 is arranged along an outer periphery of the gate pad 50 which is spaced apart from the outer peripheral gate metal portion 49-0.

The first gate runner 48-1 of the present example extends between the first main region 52-1 and the second main region 52-2, and the second gate runner 48-2 of the present example extends between the second main region 52-2 and the third main region 52-3. The first gate runner 48-1 of the present example is provided below the first emitter bridge portion 53-1, and the second gate runner 48-2 of the present example is provided below the second emitter bridge portion 53-2.

In this way, the emitter electrode 52 is divided into the plurality of main regions along a trench extension direction (Y axis direction); and between the respective main regions, the gate runner portion 48 (first gate runner 48-1, second gate runner 48-2) is provided extending in a direction (X axis direction) intersecting the trench portion. In this manner, even in the semiconductor device 100 having a large chip size, by reducing the wiring length of the gate wiring from the gate pad 50, it is possible to suppress an increase in parasitic resistance at a gate trench portion 40 and to suppress a decrease in switching withstand capability.

Further, by connecting the respective main regions by the emitter bridge portion 53, it is possible to maintain the emitter potentials in the respective main regions at the same potential. In addition, in a semiconductor module on which the semiconductor device 100 is mounted, by providing the emitter bridge portion 53, it is possible to reduce a variation in the inductance component of the wires connected to the respective main regions, and to suppress a decrease in switching withstand capability.

The semiconductor device 100 may include an edge termination structure portion between the active portion 120 and the end side 102. The edge termination structure portion reduces electric field strength on a front surface side of the semiconductor substrate 10. The edge termination structure portion may have, for example, at least one structure of a guard ring, a field plate, or a RESURF which are provided in an annular manner surrounding the active portion 120, or a structure in which a plurality of these structures are combined.

It should be noted that FIG. 1 shows the example of dividing the emitter electrode 52 into three main regions, but this is merely an illustration. The emitter electrode 52 may be divided into two main regions, or may be divided into four or more main regions. The gate runner portion 48 is provided extending in the direction (X axis direction) intersecting the trench portion between the respective main regions.

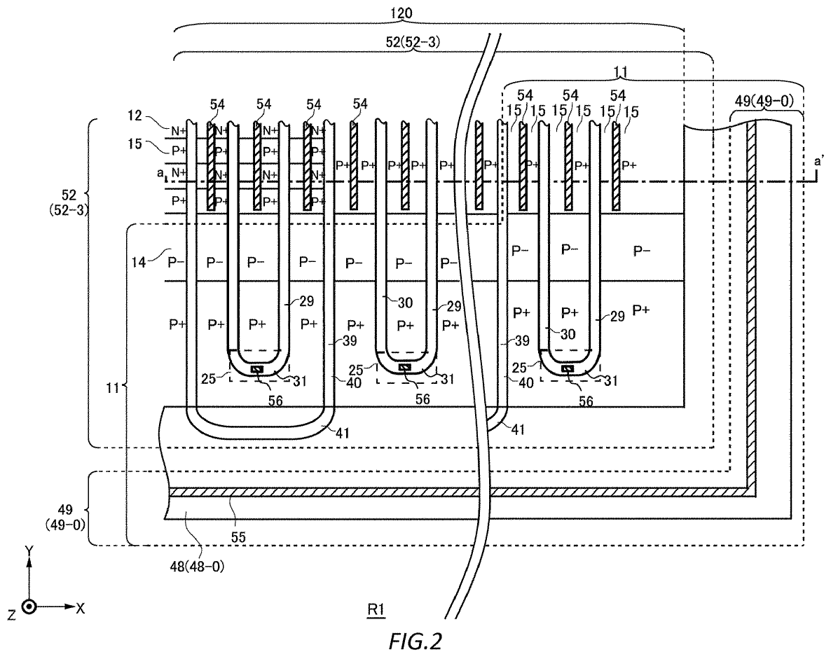

FIG. 2 is an enlarged view of a region R1 in FIG. 1. FIG. 2 shows an example of a structure near an end portion of the emitter electrode 52 in the Y axis direction. The region R1 includes: a partial region of the third main region 52-3 which is close to an end portion (close to the end side 102-3) on the positive side of the X axis direction and to the negative side (close to the end side 102-4) of the Y axis direction; and the outer peripheral gate metal portion 49-0 and the outer peripheral gate runner 48-0. Here, note that the third main region 52-3, the outer peripheral gate metal portion 49-0, and the outer peripheral gate runner 48-0 are respectively described as the emitter electrode 52, the gate metal layer 49, and the gate runner portion 48, respectively. In addition, a structure near an end portion of each main region of the emitter electrode 52 in the Y axis direction is common with the region R1, and thus the explanation is omitted.

The semiconductor device 100 includes the gate trench portion 40, a dummy trench portion 30, a well region 11, an emitter region 12, a base region 14, and a contact region 15 which are provided at the front surface of the semiconductor substrate 10. Each of the gate trench portion 40 and the dummy trench portion 30 is an example of the trench portion.

The semiconductor device 100 of the present example includes the gate metal layer 49 and the emitter electrode 52 which are provided above the front surface of the semiconductor substrate 10. The gate metal layer 49 and the emitter electrode 52 are provided separately from each other. The gate metal layer 49 and the emitter electrode 52 are electrically insulated.

Although an interlayer dielectric film is provided between the emitter electrode 52 and the gate metal layer 49, and the front surface of the semiconductor substrate 10, the illustration is omitted in FIG. 2. In the interlayer dielectric film of the present example, contact holes 54, 55, and 56 are provided penetrating the interlayer dielectric film. In FIG. 2, each contact hole is hatched with a diagonal line.

The emitter electrode 52 is provided above the gate trench portion 40, the dummy trench portion 30, the well region 11, the emitter region 12, the base region 14, and the contact region 15. The emitter electrode 52 is electrically connected to the emitter region 12, the base region 14, and the contact region 15, at the front surface of the semiconductor substrate 10, by the contact hole 54.

In addition, the emitter electrode 52 is connected to a dummy conductive portion in the dummy trench portion 30, by the contact hole 56. Between the emitter electrode 52 and the dummy conductive portion, a connection portion 25 formed of a conductive material such as polysilicon doped with impurities may be provided. The connection portion 25 is provided at the front surface of the semiconductor substrate 10 via a dielectric film such as the interlayer dielectric film and a dummy dielectric film of the dummy trench portion 30.

The gate metal layer 49 is electrically connected to the gate runner portion 48 by the contact hole 55. The gate runner portion 48 may be formed of polysilicon doped with impurities, or the like. The gate runner portion 48 is connected to the gate conductive portion in the gate trench portion 40 at the front surface of the semiconductor substrate 10. The gate runner portion 48 is not electrically connected to the dummy conductive portion in the dummy trench portion 30 and the emitter electrode 52.

The gate runner portion 48 and the emitter electrode 52 are electrically separated by an insulator such as the interlayer dielectric film and an oxide film. The gate runner portion 48 of the present example is provided from below the contact hole 55 to an edge part 41 of the gate trench portion 40. At the edge part 41 of the gate trench portion 40, the gate conductive portion is exposed on the front surface of the semiconductor substrate 10, and is connected to the gate runner portion 48.

The emitter electrode 52 and the gate metal layer 49 are formed of a conductive material including metal. For example, at least partial regions of the emitter electrode 52 and the gate metal layer 49 are formed of aluminum or an alloy in which a main component is aluminum, for example, a metal alloy such as AlSi or AlSiCu. The emitter electrode 52 and the gate metal layer 49 may have barrier metal formed of titanium, titanium nitride, or the like, below the region formed of aluminum or the like. The barrier metal may be in contact with the semiconductor substrate 10. The emitter electrode 52 and the gate metal layer 49 may have a metal plug formed of tungsten or the like below the region formed of aluminum or the like.

In the top view of the semiconductor substrate 10, the well region 11 is provided overlapping with the gate runner portion 48. The well region 11 is provided extending with a predetermined width even in a range that does not overlap with the gate runner portion 48. The well region 11 of the present example is provided away from an end portion of the contact hole 54 in the Y axis direction toward a gate runner portion 48 side. The well region 11 is a region of a second conductivity type having a higher doping concentration than that of the base region 14. The gate runner portion 48 is electrically insulated from the well region 11.

The base region 14 of the present example is of the P-type, and the well region 11 is of the P+ type. In addition, the well region 11 is formed from the front surface of the semiconductor substrate 10 to a position deeper than a lower end of the base region 14. The base region 14 is provided in contact with the well region 11. Therefore, the well region 11 is electrically connected to the emitter electrode 52.

The active portion 120 is provided with a plurality of trench portions arrayed in an array direction. The extension direction of the trench portion of the present example is perpendicular to the array direction, and the array direction is the X axis direction and the extension direction is the Y axis direction. The plurality of trench portions has a plurality of gate trench portions 40.

In the present example, at least one end portion of the gate trench portion 40 in the Y axis direction is provided below the gate metal layer 49. The gate trench portion 40 of the present example may have two linear parts 39 (parts of a trench which are linear along the extension direction) extending along the Y axis direction, and the edge part 41 connecting the two linear parts 39.

In the top view of the semiconductor substrate 10, at least a part of the edge part 41 may be provided in a curved shape. The edge part 41 connects end portions of the two linear parts 39 in the Y axis direction for connecting to the gate runner portion 48, thereby causing the gate trench portion 40 to function as the gate electrode. On the other hand, by setting the edge part 41 in a curved shape, the electric field strength at the end portion can be further reduced, in comparison with a case where the linear parts 39 makes the completion.

In the active portion 120, one or more gate trench portions 40 and one or more dummy trench portions 30 may be alternately provided along the X axis direction. The dummy trench portion 30 of the present example is provided between the respective linear parts 39 of the gate trench portion 40. In another example, between the respective linear parts 39, one dummy trench portion 30 may be provided, or a plurality of dummy trench portions 30 may be provided.

In addition, between the respective linear parts 39, the dummy trench portion 30 may not be provided, and the gate trench portion 40 may be provided. With such a structure, an electron current from the emitter region 12 can be increased, and thus an ON voltage is reduced.

The dummy trench portion 30 may have a linear shape extending in the extension direction, and may have linear parts 29 and an edge part 31 similar to the gate trench portion 40. In the present example, only the dummy trench portion 30 having the edge part 31 is provided; however, in another example, the active portion 120 may include the dummy trench portion 30 having a linear shape that does not have the edge part 31.

A diffusion depth of the well region 11 may be deeper than the depths of the gate trench portion 40 and the dummy trench portion 30. In the top view of the semiconductor substrate 10, end portions of the gate trench portion 40 and the dummy trench portion 30 in the Y axis direction are provided in the well region 11. That is, at the end portion of each trench portion in the Y axis direction, a lower end of each trench portion in the depth direction (Z axis direction) is covered with the well region 11. In addition, the trench portion provided on an end portion side of the active portion 120 in the X axis direction may be covered with the well region 11. This makes it possible to reduce the electric field strength at the lower end of each trench portion.

A mesa portion is provided between the trench portions that are adjacent to each other in the X axis direction. The mesa portion refers to a region sandwiched between the trench portions inside the semiconductor substrate 10. As an example, the range of the mesa portion in the Z axis direction is from the front surface of the semiconductor substrate 10 to the lower end of the trench portion. The mesa portion of the present example is sandwiched between the trench portions that are adjacent to each other in the X axis direction, and is provided extending in the Y axis direction along the trench portion at the front surface of the semiconductor substrate 10.

Each mesa portion is provided with the base region 14. In the top view of the semiconductor substrate 10, each mesa portion may be provided with at least one of the emitter region 12 of a first conductivity type or the contact region 15 of the second conductivity type in a region sandwiched between the base regions 14. The emitter region 12 of the present example is of the N+ type, and the contact region 15 is of the P+ type. The emitter region 12 and the contact region 15 may be provided between the base region 14 and the front surface of the semiconductor substrate 10 in the Z axis direction.

The mesa portion has the emitter region 12 exposed on the front surface of the semiconductor substrate 10. The emitter region 12 is provided in contact with the gate trench portion 40. The mesa portion in contact with the gate trench portion 40 is provided with the contact region 15 exposed on the front surface of the semiconductor substrate 10.

Each of the contact region 15 and the emitter region 12 in the mesa portion is provided from one trench portion to another trench portion in the X axis direction. As an example, the contact region 15 and the emitter region 12 in the mesa portion are alternately arranged along the extension direction (Y axis direction) of the trench portion.

In another example, the contact region 15 and the emitter region 12 in the mesa portion may be provided in a stripe shape along the extension direction (Y axis direction) of the trench portion. For example, in the top view of the semiconductor substrate 10, the emitter region 12 is provided in a region in contact with the trench portion, and the contact region 15 is provided in a region sandwiched between the emitter regions 12.

The contact hole 54 is provided above each mesa portion. The contact hole 54 is arranged in a region sandwiched between the base regions 14 in its extension direction (Y axis direction). The contact hole 54 of the present example is provided above each region of the contact region 15, the base region 14, and the emitter region 12. The contact hole 54 may be arranged at the center of the mesa portion in the array direction (X axis direction).

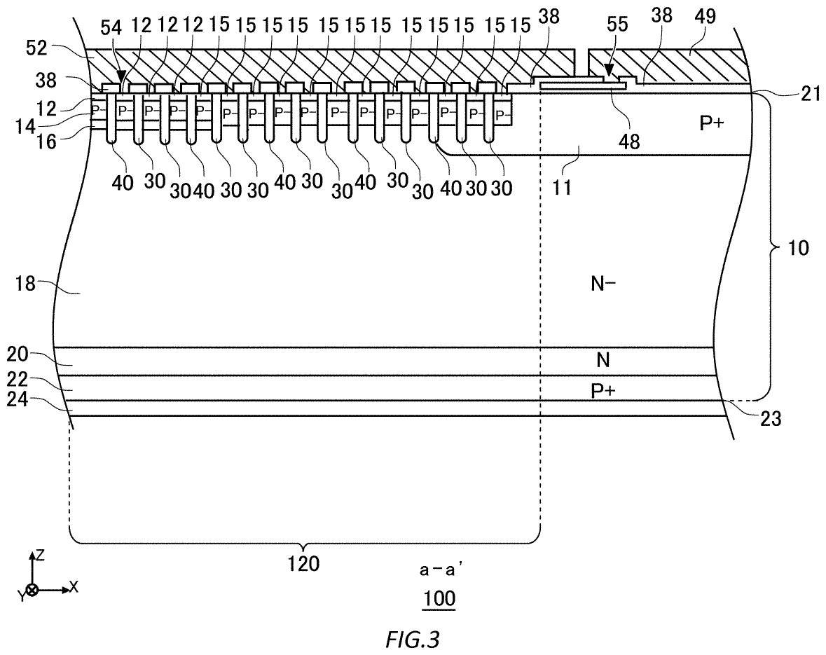

FIG. 3 is a view showing an example of a cross section a-a′ in FIG. 2. The cross section a-a′ is an XZ plane passing through the emitter region 12, the contact region 15, the base region 14, and the gate trench portion 40, and the dummy trench portion 30. In the cross section a-a′, the semiconductor device 100 of the present example has the semiconductor substrate 10, an interlayer dielectric film 38, the emitter electrode 52, and a collector electrode 24.

The interlayer dielectric film 38 is provided on a front surface 21 of the semiconductor substrate 10. The interlayer dielectric film 38 is a dielectric film such as silicate glass to which impurities such as boron or phosphorus are added. The interlayer dielectric film 38 may be in contact with the front surface 21 of the semiconductor substrate 10, or another film such as an oxide film may be provided between the interlayer dielectric film 38 and the front surface 21. The interlayer dielectric film 38 is provided with the contact holes 54, 55 described in FIG. 2.

The emitter electrode 52 is provided at the front surface 21 of the semiconductor substrate 10 and an upper surface of the interlayer dielectric film 38. The emitter electrode 52 is electrically connected to the front surface 21 of the semiconductor substrate 10, by the contact hole 54 of the interlayer dielectric film 38. A plug region of tungsten (W) or the like may be provided inside the contact holes 54, 55. The collector electrode 24 is provided at a back surface 23 of the semiconductor substrate 10. The emitter electrode 52 and the collector electrode 24 are formed of a material including metal or a laminated film thereof.

The semiconductor substrate 10 may be a silicon substrate, may be a silicon carbide substrate, or may be a nitride semiconductor substrate, such as a gallium nitride semiconductor substrate, or the like. The semiconductor substrate 10 of the present example is a silicon substrate.

The semiconductor substrate 10 has a drift region 18 of the first conductivity type. The drift region 18 of the present example is of the N-type. The drift region 18 may be a remaining region in the semiconductor substrate 10 in which other doping regions are not provided.

Above the drift region 18, one or more accumulation regions 16 may be provided in the Z axis direction. The accumulation region 16 is a region where the same dopant as that of the drift region 18 is accumulated at a higher concentration than that of the drift region 18. The doping concentration of the accumulation region 16 is higher than the doping concentration of the drift region 18. The accumulation region 16 of the present example is of the N type. By providing the accumulation region 16, it is possible to increase an injection enhancement effect (IE effect) of the carrier so as to reduce the ON voltage.

Above the base region 14, the emitter region 12 of the first conductivity type is provided in contact with the front surface 21 of the semiconductor substrate 10. The emitter region 12 of the present example is of the N+ type. The emitter region 12 is provided in contact with the gate trench portion 40. The doping concentration of the emitter region 12 is higher than the doping concentration of the drift region 18. Examples of the dopant of the emitter region 12 include arsenic (As), phosphorus (P), antimony (Sb), and the like.

Below the drift region 18, a buffer region 20 of the first conductivity type may be provided. The buffer region 20 of the present example is of the N type. Below the buffer region 20, a collector region 22 of the second conductivity type may be provided. The collector region 22 of the present example is of the P+ type. The doping concentration of the buffer region 20 is higher than the doping concentration of the drift region 18. The buffer region 20 may function as a field stop layer which prevents a depletion layer extending from a lower surface side of the base region 14, from reaching the collector region 22.

The gate trench portion 40 and the dummy trench portion 30 of the present example are provided to penetrate the base region 14 and the accumulation region 16 from the front surface 21 of the semiconductor substrate 10, and reach the drift region 18. The structure of the trench portion penetrating the doping region is not limited to the structure manufactured in order of forming the doping region and then forming the trench portion. The structure of the trench portions penetrating the doping region also includes a structure of forming the trench portions and then forming the doping region between the trench portions.

The gate trench portion 40 has a gate trench, a gate dielectric film, and a gate conductive portion which are provided at the front surface 21 of the semiconductor substrate 10. The gate dielectric film is provided covering an inner wall of the gate trench. The gate dielectric film may be formed of an oxide film or a nitride film. The gate conductive portion is provided to be embedded on an inner side further than the gate dielectric film inside the gate trench. An upper surface of the gate conductive portion may be in the same XY plane as the front surface 21 of the semiconductor substrate 10. The gate dielectric film insulates the gate conductive portion from the semiconductor substrate 10. The gate conductive portion may be formed of polysilicon doped with impurities, or the like.

The gate conductive portion may be provided to a position deeper than the lower end of the base region 14 in the depth direction (Z axis direction). The gate trench portion 40 is covered with the interlayer dielectric film 38 on the front surface 21 of the semiconductor substrate 10. When a predetermined voltage is applied to the gate conductive portion, a channel is formed by an electron inversion layer in a surface layer of the base region 14 at a boundary in contact with the gate trench.

The dummy trench portion 30 may have the same structure as that of the gate trench portion 40 in an XZ cross section. The dummy trench portion 30 has a dummy trench, a dummy dielectric film, and a dummy conductive portion which are provided at the front surface 21 of the semiconductor substrate 10. The dummy dielectric film is provided covering an inner wall of the dummy trench. The dummy dielectric film may be formed of an oxide film or a nitride film. The dummy conductive portion is provided to be embedded on an inner side further than the dummy dielectric film inside the dummy trench. An upper surface of the dummy conductive portion may be in the same XY plane as the front surface 21 of the semiconductor substrate 10. The dummy dielectric film insulates the dummy conductive portion from the semiconductor substrate 10. The dummy conductive portion may be formed of the same material as that of the gate conductive portion.

The gate trench portion 40 and the dummy trench portion 30 of the present example are covered with the interlayer dielectric film 38 on the front surface 21 of the semiconductor substrate 10. It should be noted that the lower ends of the dummy trench portion 30 and the gate trench portion 40 may have curved surfaces which are convex downward (curved shapes in the XZ cross section).

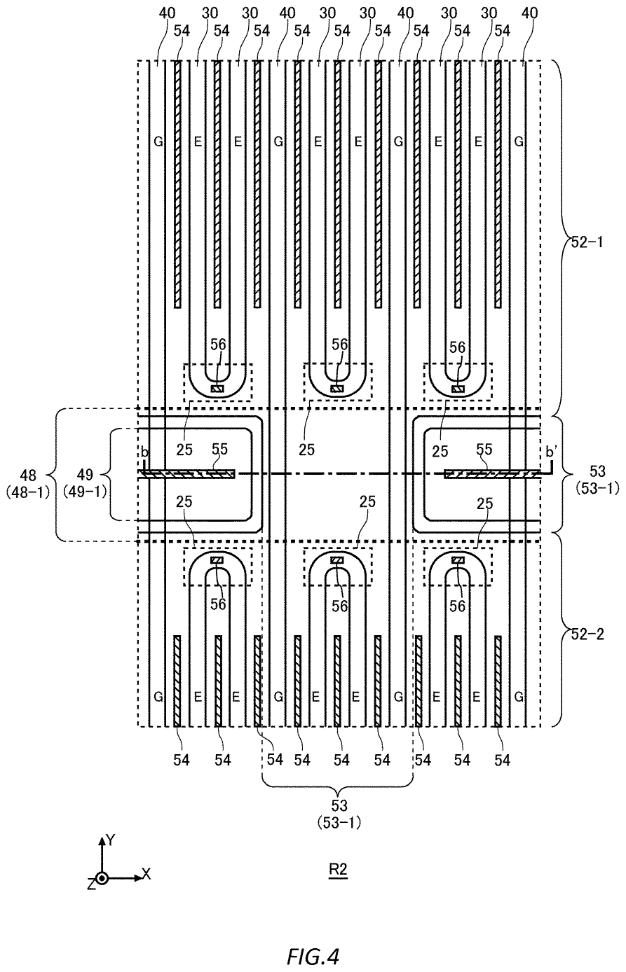

FIG. 4 is an enlarged view of a region R2 in FIG. 1. The region R2 shows an example of a structure near the first emitter bridge portion 53-1. FIG. 4 shows the main regions 52-1 and 52-2, the first gate metal portion 49-1, the first gate runner 48-1, the connection portion 25, the gate trench portion 40, and the dummy trench portion 30, and another member is omitted. In FIG. 4, the gate trench portion 40 is indicated by a symbol G, and the dummy trench portion 30 is indicated by a symbol E. It should be noted that the structure near the second emitter bridge portion 53-2 can be applied by replacing the main regions 52-1 and 52-2, the first gate metal portion 49-1, and the first gate runner 48-1 in FIG. 4 with the main regions 52-2 and 52-3, the second gate metal portion 49-2, and the second gate runner 48-2, and thus the description will be omitted here.

The first main region 52-1 and the second main region 52-2 of the present example are provided spaced apart in the Y axis direction, and are connected by the first emitter bridge portion 53-1. In the present example, the first gate metal portion 49-1 and the first gate runner 48-1 extend in the X axis direction between the first main region 52-1 and the second main region 52-2. FIG. 4 shows the first gate runner 48-1 by a dotted line. The first gate runner 48-1 is provided below the first gate metal portion 49-1, and is connected to the first gate metal portion 49-1 by the contact hole 55.

The first gate runner 48-1 of the present example is provided below the first emitter bridge portion 53-1. That is, the first gate runner 48-1 of the present example is provided extending in the X axis direction from one side to another side of the outer peripheral gate runner 48-0 extending in the Y axis direction.

The first gate metal portion 49-1 of the present example is provided spaced apart from the first main region 52-1 and the second main region 52-2. The first gate metal portion 49-1 of the present example extends in the X axis direction from the outer peripheral gate metal portion 49-0 extending in the Y axis direction, and terminates without contacting the first emitter bridge portion 53-1. That is, in the top view of the semiconductor substrate 10, in the region surrounded by the first main region 52-1, the second main region 52-2, and the first emitter bridge portion 53-1, the first gate metal portion 49-1 of the present example is provided spaced apart from these. The first emitter bridge portion 53-1 is sandwiched by the first gate metal portion 49-1 in the X axis direction.

In the top view of the semiconductor substrate 10, the gate trench portion 40 and the dummy trench portion 30 have a longitudinal direction in the Y axis direction. That is, the gate trench portion 40 and the dummy trench portion 30 are provided extending in the Y axis direction. The gate trench portions 40 and the dummy trench portions 30 may have linear parts that are parallel to the Y axis direction.

The gate trench portion 40 and the dummy trench portion 30 are arranged at a predetermined interval in the X axis direction. It should be noted that an array pattern of the gate trench portion 40 and the dummy trench portion 30 is not limited to the example in FIG. 4.

In each trench portion, the end portions of two linear parts may be connected by the edge part in a curved shape. In the example of FIG. 4, the dummy trench portion 30 has two linear parts, and one edge part. In the top view of the semiconductor substrate 10, the dummy trench portion 30 of the present example does not overlap with the first gate runner 48-1. That is, in the top view of the semiconductor substrate 10, each dummy trench portion 30 of the present example is arranged to overlap with any one of the first main region 52-1, the second main region 52-2, or the third main region 52-3, and is not arranged spanning the plurality of main regions. The dummy trench portion 30 of the present example is connected to the emitter electrode 52 via the connection portions 25 provided at the edge parts at both ends in the Y axis direction. The connection portion 25 may be formed of polysilicon doped with impurities, or the like.

By providing the connection portion 25, it is possible to easily connect the dummy trench portion 30 to the emitter electrode 52.

In the top view of the semiconductor substrate 10, the gate trench portion 40 intersects with the first gate runner 48-1. That is, in the top view of the semiconductor substrate 10, the gate trench portion 40 of the present example extends in the Y axis direction from the first main region 52-1 to the second main region 52-2, beyond the first gate runner 48-1. The gate trench portion 40 of the present example is also provided below the first emitter bridge portion 53-1.

The gate trench portion 40 of the present example extends in the Y axis direction, from one side of the outer peripheral gate runner 48-0 extending in the X axis direction to another side. It should be noted that FIG. 4 shows only the linear parts of the gate trench portion 40, but the end portions of the linear parts may be connected by the edge part in a curved shape. In the top view of the semiconductor substrate 10, the gate trench portion 40 of the present example is connected to the gate runner portion 48 in the region overlapping with the gate runner portion 48.

In another example, in the top view of the semiconductor substrate 10, the gate trench portion 40 of the present example may be arranged to overlap with any one of the first main region 52-1, the second main region 52-2, or the third main region 52-3, and may not be arranged spanning the plurality of main regions. In this case, the gate trench portion 40 provided below the first main region 52-1 extends in the Y axis direction from the outer peripheral gate runner 48-0 on the positive side (close to the end side 102-2) of the Y axis direction to the first gate runner 48-1; the gate trench portion 40 provided below the second main region 52-2 extends in the Y axis direction from the first gate runner 48-1 to the second gate runner 48-2; and the gate trench portion 40 provided below the third main region 52-3 extends in the Y axis direction from the second gate runner 48-2 to the outer peripheral gate runner 48-0 on the negative side (close to the end side 102-4) of the Y axis direction.

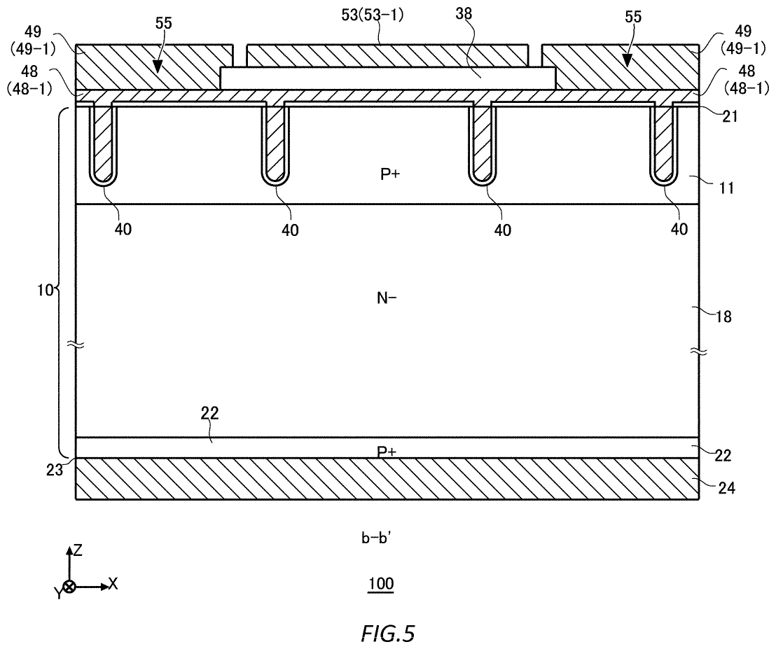

FIG. 5 is a view showing an example of a cross section b-b′ in FIG. 4. The cross section b-b′ is a XZ plane passing through the first gate runner 48-1 and the first gate metal portion 49-1, between the first main region 52-1 and the second main region 52-2.

The interlayer dielectric film 38 of the present example is provided above the front surface 21 of the semiconductor substrate 10. The first gate metal portion 49-1 of the present example is connected to the first gate runner 48-1 by the contact hole 55 provided in the interlayer dielectric film 38.

The first emitter bridge portion 53-1 of the present example is provided spaced apart from the first gate metal portion 49-1. The width of the first emitter bridge portion 53-1 in the X axis direction may be 150 μm or more and 500 μm or less. The first gate runner 48-1 of the present example is provided extending in the X axis direction below the first gate metal portion 49-1 and the first emitter bridge portion 53-1. In the gate wiring from the gate pad 50 to the gate trench portion 40 provided below the first emitter bridge portion 53-1, a ratio of gate wiring that does not include the gate metal layer 49 (gate wiring including only the first gate runner 48-1) is higher than a ratio of gate wiring from the gate pad 50 to the gate trench portion 40 provided below the first gate metal portion 49-1. A resistance value of the first gate runner 48-1 is higher than a resistance value of the first gate metal portion 49-1, and thus in the gate trench portion 40 provided below the first emitter bridge portion 53-1, a gate resistance component of the entire gate wiring is increased, and the parasitic resistance is increased.

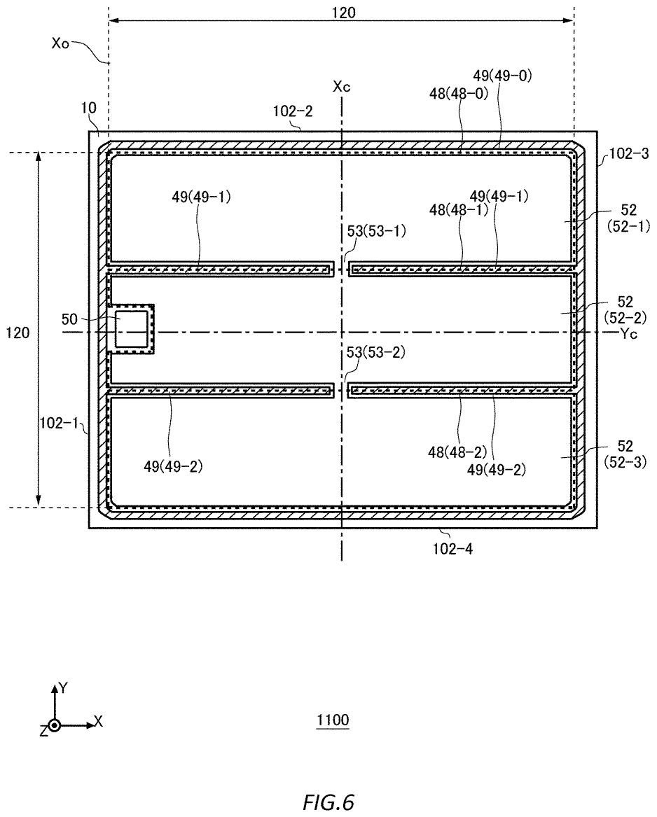

FIG. 6 is a top plan view showing an example of a semiconductor device 1100 according to a comparison example. The semiconductor device 1100 according to the comparison example differs from the semiconductor device 100 in FIG. 1 in that the first emitter bridge portion 53-1 and the second emitter bridge portion 53-2 are provided along the virtual center line Xc of the active portion 120 in the X axis direction. Other structures of the semiconductor device 1100 are common with the semiconductor device 100 described in FIG. 1 to FIG. 5, and thus the description will be omitted here.

The first emitter bridge portion 53-1 and the second emitter bridge portion 53-2 of the semiconductor device 1100 are positioned on the same virtual center line Xc in the X axis direction. Therefore, in the top view of the semiconductor substrate 10, the gate trench portion 40 which is arranged overlapping with the first emitter bridge portion 53-1, is also arranged overlapping with the second emitter bridge portion 53-2. In the top view of the semiconductor substrate 10, a region where the emitter bridge portion 53 is provided is provided with only the gate runner portion 48 having a high resistance and is not provided with the gate metal layer 49, and thus the parasitic resistance of the gate trench portion 40 arranged overlapping with the region, becomes high. In particular, in the top view of the semiconductor substrate 10, the parasitic resistance in a section between the first emitter bridge portion 53-1 and the second emitter bridge portion 53-2 becomes high, and there is a risk of causing a decrease in latch-up withstand capability and RBSOA.

In contrast to this, in the semiconductor device 100 according to the example, the gate trench portion 40 provided below the first emitter bridge portion 53-1 is different from the gate trench portion 40 provided below the second emitter bridge portion 53-2. That is, in the semiconductor device 100, the gate trench portion 40 below the first emitter bridge portion 53-1 is not provided below the second emitter bridge portion 53-2. In the semiconductor device 100, at least one end portion of the gate trench portion 40 in the Y axis direction is provided below the gate metal layer 49, and the gate trench portion 40 is provided below at least one of the first gate metal portion 49-1 or the second gate metal portion 49-2. Therefore, in the top view of the semiconductor substrate 10, in each gate trench portion 40, there is no section sandwiched between the first emitter bridge portion 53-1 and the second emitter bridge portion 53-2, and it is possible to suppress a variation in parasitic resistance.

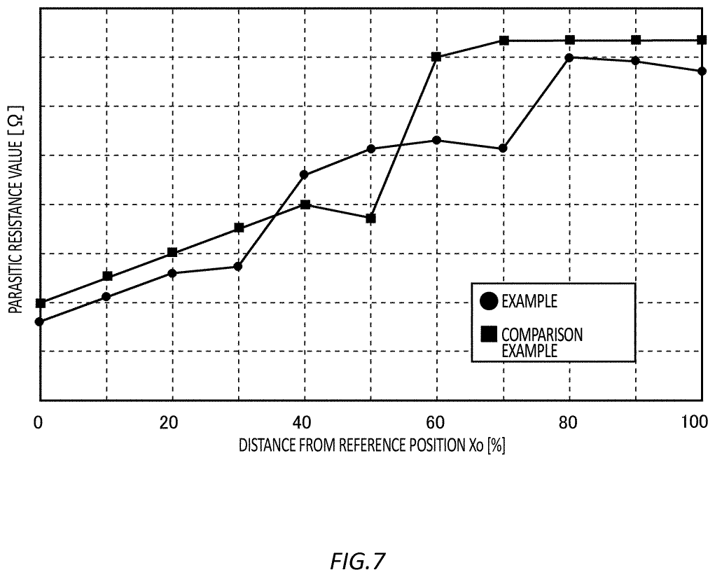

FIG. 7 is a graph showing a relationship between a position of the emitter bridge portion 53 and a parasitic resistance value in the gate trench portion 40. In FIG. 7, the horizontal axis indicates, in percentage, a distance in the X axis direction from the reference position Xo that is the position of the end portion of the active portion 120 on the gate pad 50 side, where the reference position Xo is 0 and an end portion of the active portion 120 on the opposite side (close to the end side 102-3) is 100. The vertical axis indicates the parasitic resistance value [0] in the gate trench portion 40. In FIG. 7, the parasitic resistance value in the gate trench portion 40 of the semiconductor device 100 according to the example, is plotted with a black circle; and the parasitic resistance value in the gate trench portion 40 of the semiconductor device 1100 according to the comparison example is plotted with a black square.

The parasitic resistance value in the gate trench portion 40 of the semiconductor device 100 according to the example is increased at two locations spanning the first emitter bridge portion 53-1 and the second emitter bridge portion 53-2. On the other hand, the parasitic resistance value in the gate trench portion 40 of the semiconductor device 1100 according to the comparison example is increased at only one location spanning the first emitter bridge portion 53-1 and the second emitter bridge portion 53-2; however, the magnitude of the increase is greater than the magnitude of the increase in the semiconductor device 100.

In this way, in the semiconductor device 100 according to the example, by providing the first emitter bridge portion 53-1 and the second emitter bridge portion 53-2 at positions different from each other in the X axis direction, the gate trench portion 40 is not provided below the emitter bridge portion 53, or is provided only below any one of the first emitter bridge portion 53-1 or the second emitter bridge portion 53-2. This makes it possible to suppress a steep increase in parasitic resistance value, and to distribute portions having a high resistance throughout the entire semiconductor device 100 to suppress a decrease in switching withstand capability.

Further, in the semiconductor device 100 according to the example, the first emitter bridge portion 53-1 and the second emitter bridge portion 53-2 are provided offset from each other to opposite sides with respect to the virtual center line Xc of the active portion 120, thereby making it possible to reduce a variation in emitter potential in the X axis direction.

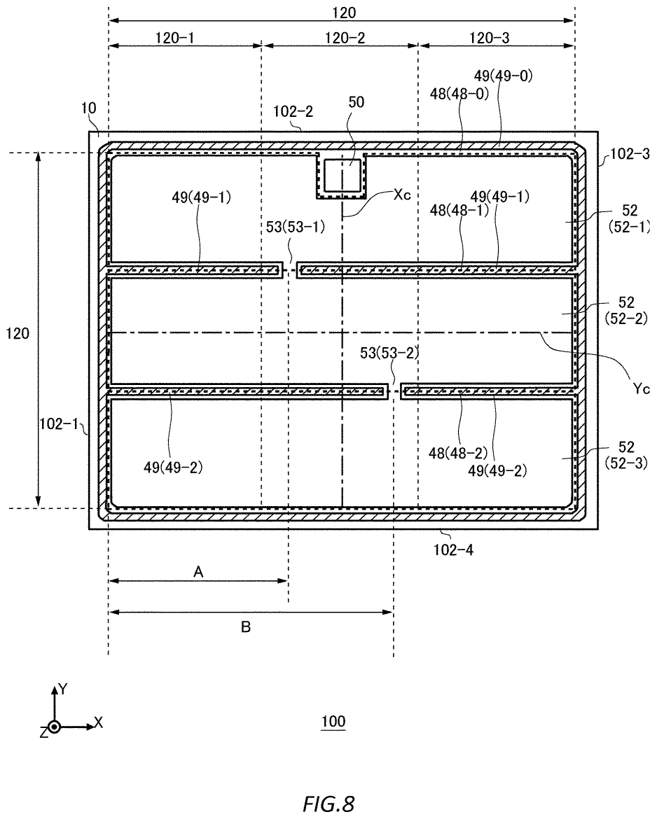

FIG. 8 is a top plan view showing another example of the semiconductor device 100 according to an embodiment. FIG. 8 differs from FIG. 1 in that the gate pad 50 is provided on the positive side (closer to the end side 102-2) of the Y axis direction further than the active portion 120 is. Other structures are common with the semiconductor device 100 described in FIG. 1 to FIG. 5, and thus the description will be omitted here.

In the present example, the first emitter bridge portion 53-1 and the second emitter bridge portion 53-2 are arranged similarly to those in FIG. 1 to FIG. 5, thereby making it possible to obtain the same effect as that of the semiconductor device 100 described in FIG. 1 to FIG. 5, regardless of the position of the gate pad 50.

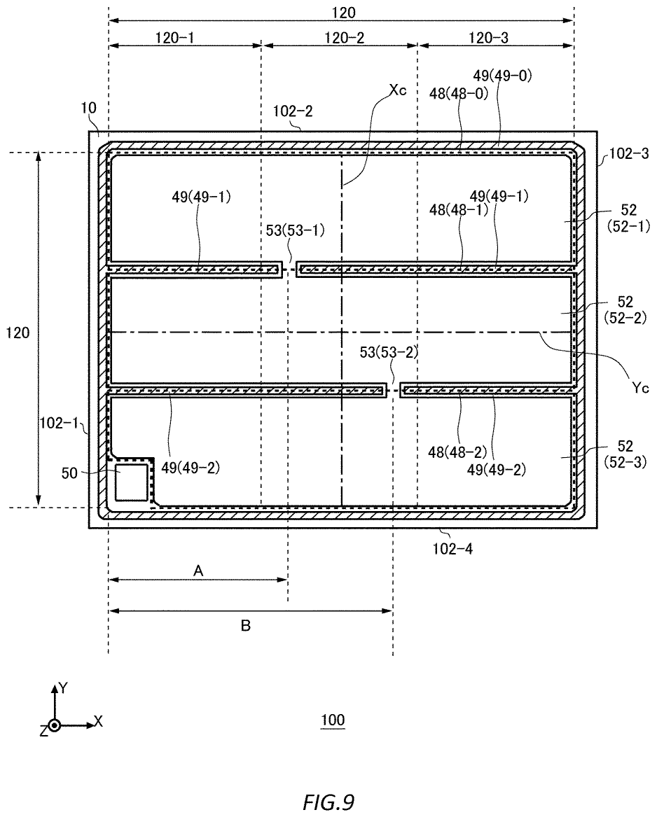

FIG. 9 is a top plan view showing another example of the semiconductor device 100 according to an embodiment. FIG. 9 differs from FIG. 1 in that the gate pad 50 is provided close to a corner region of the active portion 120, that is, it is provided on the negative side (close to the end side 102-4) of the Y axis direction, relative to a virtual center line Yc of the active portion 120 in the Y axis direction. Other structures are common with the semiconductor device 100 described in FIG. 1 to FIG. 5, and thus the description will be omitted here.

In the present example, the first emitter bridge portion 53-1 and the second emitter bridge portion 53-2 are arranged similarly to those in FIG. 1 to FIG. 5, thereby making it possible to obtain the same effect as that of the semiconductor device 100 described in FIG. 1 to FIG. 5, regardless of the position of the gate pad 50. It should be noted that in FIG. 9, the gate pad 50 is provided on the negative side (close to the end side 102-4) of the Y axis direction, relative to the virtual center line Yc; however, the same applies to a case where it is provided on the positive side (close to the end side 102-2) of the Y axis direction, relative to the virtual center line Yc.

While the present invention has been described hereinabove by using the embodiment, a technical scope of the present invention is not limited to a scope of the above-described embodiment. It is apparent to persons skilled in the art that various changes or improvements may be made to the embodiment described above. It is also apparent from the scope of the claims that the embodiments added with such alterations or improvements can be included in the technical scope of the invention.

It should be noted that each process of the operations, procedures, steps, stages, and the like performed by the device, system, program, and method shown in the claims, specification, and drawings may be executed in any order as long as the order is not particularly explicitly indicated by “before”, “prior to”, or the like and as long as an output from a previous process is not used in a later process. Even if the operation flow is described using phrases such as “first” or “next” in the claims, the description, and the drawings, it does not necessarily mean that it must be performed in this order.

### EXPLANATION OF REFERENCES

10: semiconductor substrate; 11: well region; 12: emitter region; 14: base region; 15: contact region; 16: accumulation region; 18: drift region; 20: buffer region; 21: front surface; 22: collector region; 23: back surface; 24: collector electrode; 25: connection portion; 29: linear part; 30: dummy trench portion; 31: edge part; 38: interlayer dielectric film; 39: linear part; 40: gate trench portion; 41: edge part; 48: gate runner portion; 48-0: outer peripheral gate runner; 48-1: first gate runner; 48-2: second gate runner; 49: gate metal layer; 49-0: outer peripheral gate metal portion; 49-1: first gate metal portion; 49-2: second gate metal portion; 50: gate pad; 52: emitter electrode; 52-1: first main region; 52-2: second main region; 52-3: third main region; 53: emitter bridge portion; 53-1: first emitter bridge portion; 53-2: second emitter bridge portion; 54: contact hole; 55: contact hole; 56: contact hole; 100: semiconductor device; 102: end side; 120: active portion; 120-1: first active region; 120-2: second active region; 120-3: third active region; 1100: semiconductor device.

What is claimed is:

1. A semiconductor device comprising:
a drift region of a first conductivity type which is provided in a semiconductor substrate;
a base region of a second conductivity type which is provided above the drift region;
an emitter region of the first conductivity type which is provided above the drift region, and which has a doping concentration higher than that of the drift region;
a plurality of contact regions of the second conductivity type which are provided above the drift region, and which have doping concentrations higher than that of the base region;
a plurality of trench portions which extend in a predetermined trench extension direction, at a front surface of the semiconductor substrate;
an emitter electrode which is provided above the semiconductor substrate, and which has a first main region, a second main region, and a third main region;
a gate pad which is provided above the semiconductor substrate;
a gate metal layer which is electrically connected to the gate pad; and
a gate runner portion which is electrically connected to the gate metal layer, wherein
the plurality of trench portions have a plurality of gate trench portions,
the emitter electrode has:
a first emitter bridge portion which connects the first main region to the second main region; and
a second emitter bridge portion which connects the second main region to the third main region, and
below the first emitter bridge portion, a gate trench portion that is different from a gate trench portion which is provided below the second emitter bridge portion is provided.

2. The semiconductor device according to claim 1, wherein
the gate trench portion below the first emitter bridge portion is not provided below the second emitter bridge portion.

3. The semiconductor device according to claim 1, wherein
the first emitter bridge portion is arranged at a position different from that of the second emitter bridge portion in a trench array direction.

4. The semiconductor device according to claim 1, wherein
the gate metal layer has:
a first gate metal portion which extends between the first main region and the second main region; and
a second gate metal portion which extends between the second main region and the third main region, and
the plurality of gate trench portions are provided below at least one of the first gate metal portion or the second gate metal portion.

5. The semiconductor device according to claim 1, wherein
the gate runner portion has:
a first gate runner which extends in a trench array direction between the first main region and the second main region; and
a second gate runner which extends in the trench array direction between the second main region and the third main region.

6. The semiconductor device according to claim 5, wherein
the first emitter bridge portion is sandwiched by the gate metal layer in the trench array direction, and
the second emitter bridge portion is sandwiched by the gate metal layer in the trench array direction.

7. The semiconductor device according to claim 5, wherein
the first gate runner is provided below the first emitter bridge portion, and
the second gate runner is provided below the second emitter bridge portion.

8. The semiconductor device according to claim 6, wherein
at least one end portion of each of the plurality of gate trench portions in the trench extension direction is provided below the gate metal layer.

9. The semiconductor device according to claim 1, wherein
the gate pad is provided closer to an end side of the semiconductor substrate in a trench array direction than an active portion is.

10. The semiconductor device according to claim 9, wherein
the first emitter bridge portion is provided closer to the gate pad than a virtual center line of the active portion in the trench array direction, and
the second emitter bridge portion is provided spaced apart from the gate pad farther than the virtual center line.

11. The semiconductor device according to claim 10, wherein
in the trench array direction, a distance between the first emitter bridge portion and an end portion of the active portion on a side of the gate pad is 2.5% or more and 97.5% or less of a distance between the second emitter bridge portion and the end portion of the active portion on the side of the gate pad.

12. The semiconductor device according to claim 10, comprising:
a first active region, a second active region, and a third active region which are obtained by dividing the active portion into three equal parts in the trench array direction,
the first active region being close to the gate pad,
the second active region being spaced apart from the gate pad farther than the first active region, and
the third active region being spaced apart from the gate pad farther than the second active region, wherein
the first emitter bridge portion and the second emitter bridge portion are provided in the second active region.

13. The semiconductor device according to claim 10, wherein
in the trench array direction, a distance between the first emitter bridge portion and the second emitter bridge portion is 150 μm or more and 500 μm or less.

14. The semiconductor device according to claim 10, wherein
in the trench array direction, a distance between the first emitter bridge portion and the virtual center line is equal to a distance between the second emitter bridge portion and the virtual center line.

15. The semiconductor device according to claim 10, wherein
in the trench array direction, a distance between the first emitter bridge portion and an end portion of the active portion on a side of the gate pad is 40% or more and 60% or less of a distance between the second emitter bridge portion and the end portion of the active portion on the side of the gate pad.

16. The semiconductor device according to claim 1, wherein
the gate pad is provided closer to an end side of the semiconductor substrate in the trench extension direction than an active portion is.

17. The semiconductor device according to claim 9, wherein
the gate pad is provided closer to an end side of the semiconductor substrate than a virtual center line of the active portion in the trench extension direction.
